(19) United States
(12) Patent Application Publication
(10) Pub. No.: US 2025/0129514 A1
(43) Pub. Date: Apr. 24, 2025

(54) METHOD FOR PRODUCING GROUP III NITRIDE CRYSTALS

(71) Applicants: PANASONIC HOLDINGS CORPORATION, Osaka (JP); OSAKA UNIVERSITY, Osaka (JP)

(72) Inventors: Tomio YAMASHITA, Gifu (JP); Yoshio OKAYAMA, Shiga (JP); Yusuke MORI, Osaka (JP); Masashi YOSHIMURA, Osaka (JP); Masayuki IMANISHI, Osaka (JP); Kousuke MURAKAMI, Osaka (JP)

(73) Assignees: PANASONIC HOLDINGS CORPORATION, Osaka (JP); OSAKA UNIVERSITY, Osaka (JP)

(21) Appl. No.: 18/990,573

(22) Filed: Dec. 20, 2024

Related U.S. Application Data
(63) Continuation of application No. PCT/JP2023/021371, filed on Jun. 8, 2023.

(30) Foreign Application Priority Data
Jul. 6, 2022 (JP) 2022-109149

(51) Int. Cl. C30B 25/20; C30B 29/40; C30B 29/66

(52) U.S. Cl. CPC C30B 25/20; C30B 29/406; C30B 29/66

(57) ABSTRACT

A method for manufacturing a Group III nitride crystal, the method including: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method includes: growing a plurality of island-like Group III nitride crystal nuclei on the surface of the Group III nitride seed crystal; growing a first Group III nitride crystal having an inverted triangular shape or a trapezoidal shape in section from each of the plurality of island-like Group III nitride crystal nuclei; and growing a second Group III nitride crystal such that the second Group III nitride crystal fills a depression of the first Group III nitride crystal to form the second Group III nitride crystal having a flat surface, wherein in the course of growing the plurality of island-like Group III nitride crystal nuclei, a temperature is set to 875° C. or more and a nucleation density is set to 1*10⁶/cm² or less, and in the course of growing the first Group III nitride crystal and growing the second Group III nitride crystal, immersion of the Group III nitride seed crystal in the melt and pulling up from the melt are repeated a plurality of times.

### CROSS-REFERENCE TO RELATED APPLICATIONS

This application claims priority of Japanese Patent Application No. 2022-109149 filed on Jul. 6, 2022, the contents of which is incorporated herein by reference.

### BACKGROUND

### 1. Technical Field

The present disclosure relates to a method for manufacturing a Group III nitride crystal

### 2. Description of the Related Art

Group III nitrides, which are materials for blue LED elements, which are display devices, or for power devices for vehicle-mounted applications and the like, have recently been attracting attention. Particularly, Group III nitrides are expected to be applied as a power device and have superior performance such as high withstand voltage and high temperature resistance characteristics as compared to currently commercially available Si. One of known methods of manufacturing a crystal of such a Group Ill nitride is a flux method in which a Group III element is reacted with nitrogen in an alkali metal melt (flux) of Na or the like to grow a high-quality crystal with less crystal defect (dislocation), as shown in JP 4538596 B2. In addition, there are disclosed methods in which, to obtain Group Ill nitride crystals having a large size of 4 inches or more, multiple portions of a Group III nitride layer formed on a sapphire substrate by metal-organic chemical vapor deposition (MOCVD) are selected as seed crystals and the seed crystals are brought into contact with an alkali metal melt to grow a group III nitride crystal, as shown in JP 4588340 B2, JP 5904421 B2, and JP 2020-132464 A.

### SUMMARY

However, in the case of producing a single piece of Group III nitride wafer from multiple seed crystals disclosed in JP 2020-132464 A, although good crystallinity can be obtained, there is a problem that dislocations are concentrated in a region (triple point) surrounded by multiple seed crystals. FIG. 1 shows X-Ray Rocking Curve (XRC) data of a Group III nitride crystal produced by a conventional manufacturing method. In addition, FIGS. 2 and 3 each show a 250 μm square field image of multiphoton-excitation photoluminescence (MPPL) taken by imaging a crystal surface. The conventional crystal exhibits good crystallinity of 19 to 45 arcsec as shown by the XRC of FIG. 1, but it can be seen that there is a region where the dislocation density is locally high as shown in the MPPL image of FIG. 2. FIG. 3 is an MPPL image of a lower layer portion at the same place as FIG. 2, and it can be seen that the lower layer portion is located on a region (triple point) surrounded by the multiple seed crystals described above. The dislocation density is the fourth power/cm² range or less outside this region, but the dislocation density is the fifth power/cm² range in the region surrounded by the multiple seed crystals.

The present disclosure is intended to solve the above-mentioned conventional problems, and one non-limiting and exemplary embodiments provides a method (regrowth) for manufacturing a high-quality Group III nitride crystal by a flux method.

In one general aspect, the techniques disclosed here feature: a method for manufacturing a Group III nitride crystal, including: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method includes:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a temperature is set to 875° C. or more and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

In another general aspect, the techniques disclosed here feature: a method for manufacturing a Group III nitride crystal, the method including: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method includes:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a gas pressure in a reaction chamber is set to a pressure of 2*10⁶ Pa or less and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

In further general aspect, the techniques disclosed here feature: a Group III nitride crystal that is a Group III nitride crystal grown on a Group III nitride seed crystal, wherein a nucleation density at a growth interface on the Group III nitride seed crystal is 1*10⁶/cm² or less.

When the methods for manufacturing a Group III nitride crystal according to the present disclosure are used, a high-quality Group III nitride can be manufactured by a flux method.

Additional benefits and advantages of the disclosed embodiments will be apparent from the specification and figures. The benefits and/or advantages may be individually provided by the various embodiments and features of the specification and drawings disclosure, and need not all be provided in order to obtain one or more of the same.

### BRIEF DESCRIPTION OF DRAWINGS

The present disclosure will become readily understood from the following description of non-limiting and exemplary embodiments thereof made with reference to the accompanying drawings, in which like parts are designated by like reference numeral and in which:

FIG. 1 is a diagram indicating an X-ray rocking curve (XRC) of a Group III nitride crystal produced by a conventional manufacturing method;

FIG. 2 is a 250 μm square field image of multiphoton-excitation photoluminescence (MPPL) showing a surface dislocation image near a surface of a Group III nitride crystal produced by a conventional manufacturing method;

FIG. 3 is an MPPL image showing a surface dislocation image near a pyramidal portion of a Group III nitride crystal produced by a conventional manufacturing method;

FIG. 4 is a table showing the proportion of dislocation density in a plane of a Group III nitride crystal produced by a conventional method for manufacturing a Group III nitride crystal;

FIG. 5 is a table showing the proportion of dislocation density in a plane of a Group III nitride crystal produced by a method for manufacturing a Group III nitride crystal according to the present disclosure;

FIG. 6 is a schematic sectional view illustrating a sectional structure of one example of a substrate for producing a Group III nitride crystal to be used in the method for manufacturing a Group III nitride crystal according to first embodiment of the present disclosure;

FIG. 7 is a schematic sectional view illustrating a sectional structure in a state where a substrate is pulled up above a melt in a Group III nitride crystal manufacturing apparatus to be used in the method for manufacturing a Group III nitride crystal according to first embodiment of the present disclosure;

FIG. 8 is a schematic sectional view illustrating a sectional structure in a state where a substrate is immersed in a melt in a Group III nitride crystal manufacturing apparatus to be used in the method for manufacturing a Group III nitride crystal according to first embodiment of the present disclosure;

FIG. 9 is a schematic sectional view illustrating one step of the method for manufacturing a Group III nitride crystal according to first embodiment of the present disclosure;

FIG. 10 is a schematic sectional view illustrating one step of the method for manufacturing a Group III nitride crystal according to first embodiment of the present disclosure;

FIG. 11 is a schematic sectional view illustrating one step of the method for manufacturing a Group III nitride crystal according to first embodiment of the present disclosure;

FIG. 12 is a schematic sectional view illustrating one step of the method for manufacturing a Group III nitride crystal according to first embodiment of the present disclosure;

FIG. 13 is a diagram illustrating a temperature profile of one example of the method for manufacturing a Group III nitride crystal according to first embodiment of the present disclosure;

FIG. 14 is a diagram illustrating a temperature profile of one example of a conventional method for manufacturing a Group III nitride crystal;

FIG. 15 is a schematic sectional view illustrating one step of a conventional method for manufacturing a Group III nitride crystal;

FIG. 16 is a schematic sectional view illustrating one step of a conventional method for manufacturing a Group III nitride crystal;

FIG. 17 is a schematic sectional view illustrating one step of a conventional method for manufacturing a Group III nitride crystal;

FIG. 18 is a diagram showing a comparison among 250 μm square field images of multiphoton-excitation photoluminescence (MPPL) near a growth interface in a nucleation step of a Group III nitride crystal in methods for manufacturing a Group III nitride crystal according to first embodiment of the present disclosure and 250 μm square field images of multiphoton-excitation photoluminescence (MPPL) near a growth interface in a nucleation step of a Group III nitride crystal in conventional examples; and

FIG. 19 is a diagram showing a comparison among 250 μm square field images of multiphoton-excitation photoluminescence (MPPL) near growth surfaces of Group III nitride crystals to be used in first embodiment of the present disclosure and a 250 μm square field image of multiphoton-excitation photoluminescence (MPPL) near a growth surface of a Group III nitride crystal to be used in a conventional example.

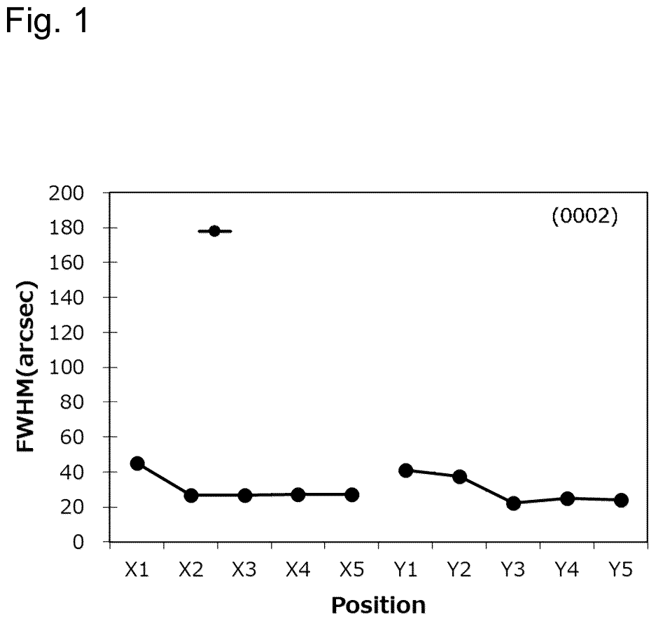

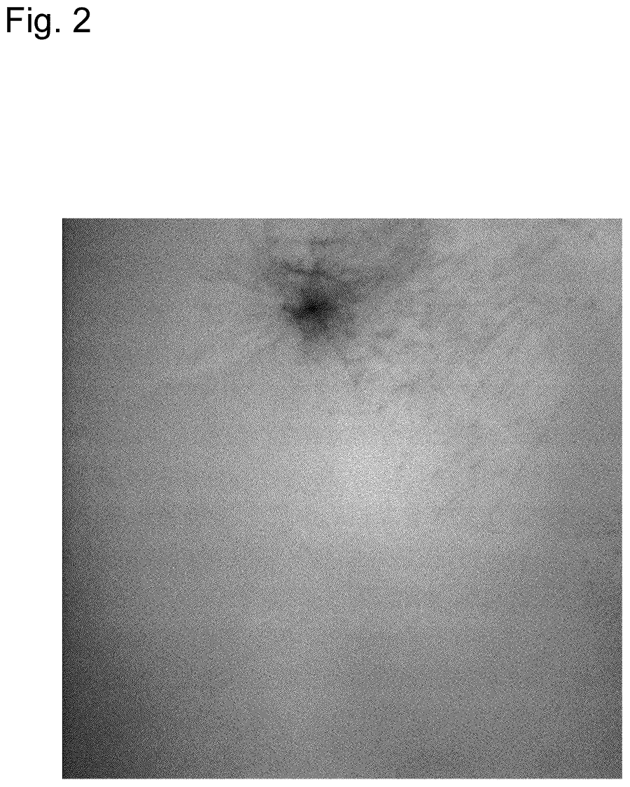

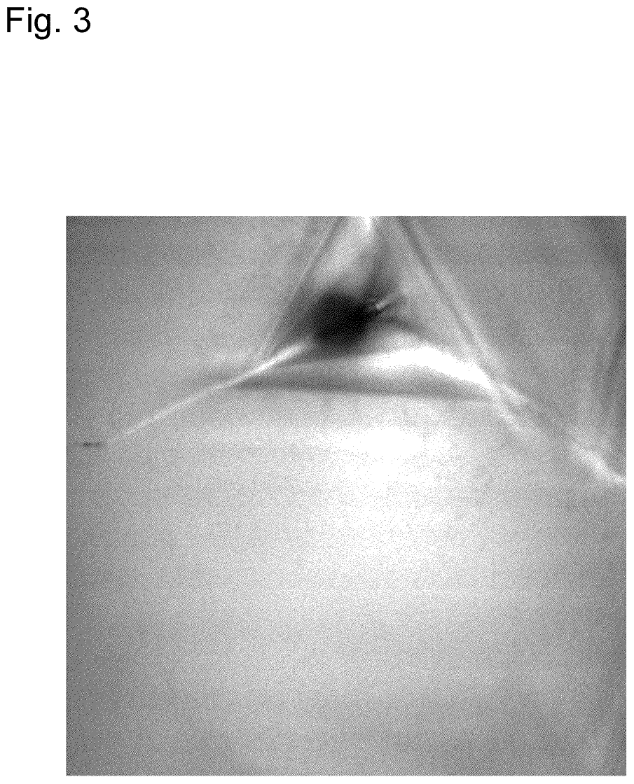

### DETAILED DESCRIPTION

A method for manufacturing a Group III nitride crystal according to a first aspect, including: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method includes:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a temperature is set to 875° C. or more and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

Further, as a method for manufacturing a Group III nitride crystal of a second aspect, in the first aspect, in the course of growing the plurality of island-like Group III nitride crystal nuclei, the plurality of island-like Group III nitride crystal nuclei may be grown by setting the temperature to 880° C. or more and thereby lowering the nucleation density.

Further, as a method for manufacturing a Group III nitride crystal of a third aspect, in the first aspect, in the course of growing the plurality of island-like Group III nitride crystal nuclei, the plurality of island-like Group III nitride crystal nuclei may be grown by setting the temperature to 885° C. or more and less than 900° C., thereby lowering the nucleation density.

Further, as a method for manufacturing a Group III nitride crystal of a fourth aspect, the method including: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method includes:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a gas pressure in a reaction chamber is set to a pressure of 2*10⁶ Pa or less and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

Further, as a method for manufacturing a Group III nitride crystal of a fifth aspect, in any one of the first to fourth aspects, the Group III nitride seed crystal may be a low dislocation substrate having a dislocation density of 5*10⁵/cm² or less.

A Group III nitride crystal according to a sixth aspect is a Group III nitride crystal grown on a Group III nitride seed crystal, wherein a nucleation density at a growth interface on the Group III nitride seed crystal is 1*10⁶/cm² or less.

Hereinafter, a method for manufacturing a Group III nitride crystal according to an embodiment of the present disclosure will be described with reference to accompanying drawings, taking as an example an embodiment in which a GaN crystal is produced as a Group III nitride crystal.

### First Embodiment

The method for manufacturing a Group III nitride crystal according to first embodiment is a method for manufacturing a Group III nitride crystal, the method involving reacting a Group III element and nitrogen in a melt to grow a Group III nitride crystal on a Group III nitride seed crystal. The melt contains at least one Group III element selected from among gallium, aluminum, and indium, and an alkali metal. A surface of the Group III nitride seed crystal is brought into contact with the melt in an atmosphere containing nitrogen, and a Group III nitride crystal is thereby grown. This method for manufacturing a Group III nitride crystal includes a nucleation step, a first crystal growth step of growing a first Group III nitride crystal, and a second crystal growth step of growing a second Group III nitride crystal. In the first crystal growth step, a first Group III nitride crystal having an inverted triangular shape or a trapezoidal shape in section is grown from each of multiple island-like Group III nitride crystal nuclei. In the second crystal growth step, a second Group III nitride crystal is grown so as to fill a depression of the first Group III nitride crystal to make the surface flat. In the nucleation step, the nucleation density can be reduced to 1*10⁶/cm² or less by adjusting the temperature to 875° C. or more. In the first and second crystal growth steps, immersion of the Group III nitride seed crystal in the melt and pulling up of the Group III nitride seed crystal from the melt are repeated multiple times.

When the method for manufacturing a Group III nitride crystal according to first embodiment is used, a high-quality thick Group III nitride can be manufactured (regrown) by a flux method by using, for example, a single piece of Group III nitride wafer produced from multiple seed crystals disclosed in Patent Document 4 as a seed substrate. Also, when a Group III nitride wafer produced by a hydride vapor phase epitaxy (HVPE) method or the like is used as a seed substrate, a high-quality thick Group III nitride can be provided by a flux method.

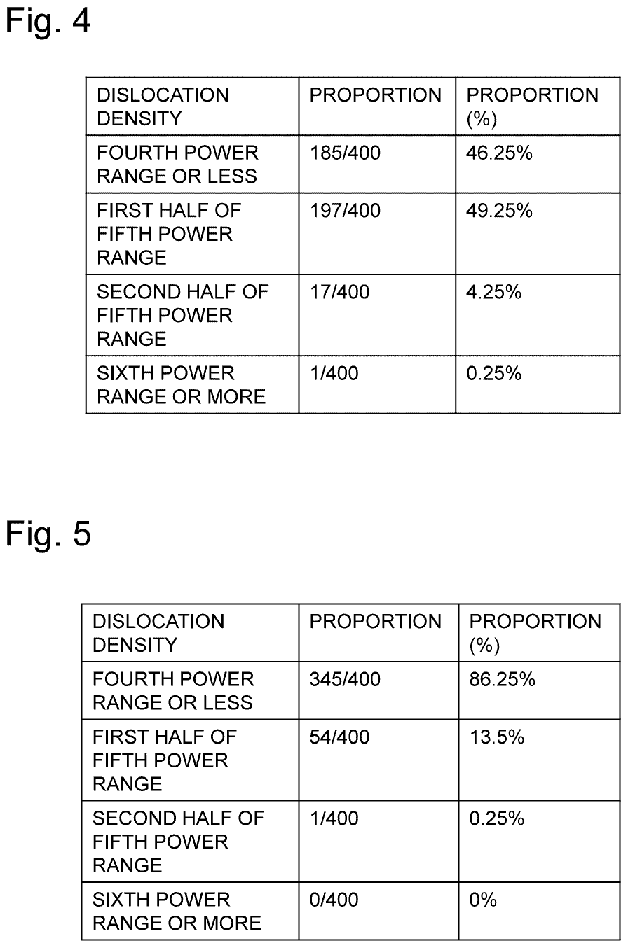

This method for manufacturing a Group III nitride crystal makes it possible to reduce dislocations at a place where dislocations are locally concentrated in a conventional manufacturing method for manufacturing a large-sized Group III nitride crystal by growing Group III nitride crystals from multiple seed crystals and combining the grown crystals, namely, at a region (triple point) surrounded by the multiple seed crystals described above. FIG. 4 shows the result of observing a crystal surface produced in a conventional example by multiphoton-excitation photoluminescence and evaluating the dislocation density at 400 places (5 mm square region) in a plane. Places having a dislocation density in the fourth power/cm² range accounted for 46%, and places having a dislocation density of the fifth power/cm² range or more accounted for about 54%. FIG. 5 shows the result of evaluating in the same manner the dislocation density of a crystal surface produced in the present disclosure. It is found that in the present disclosure, the places where the dislocation density is the fourth power/cm² range increase to 86%. As described above, according to the present disclosure, it is possible to manufacture a Group III nitride crystal substrate having few crystal defects in a manufacturing method for manufacturing a Group III nitride crystal.

Hereinafter, the steps included in this method for manufacturing a Group III nitride crystal will be described.

### GaN Crystal Growth Step

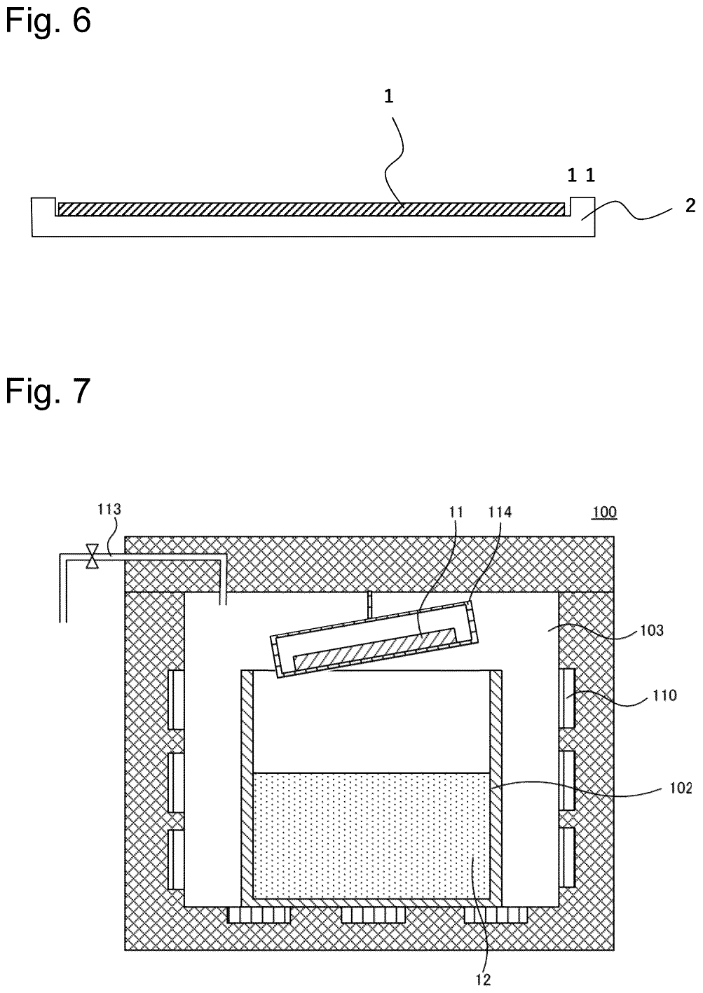

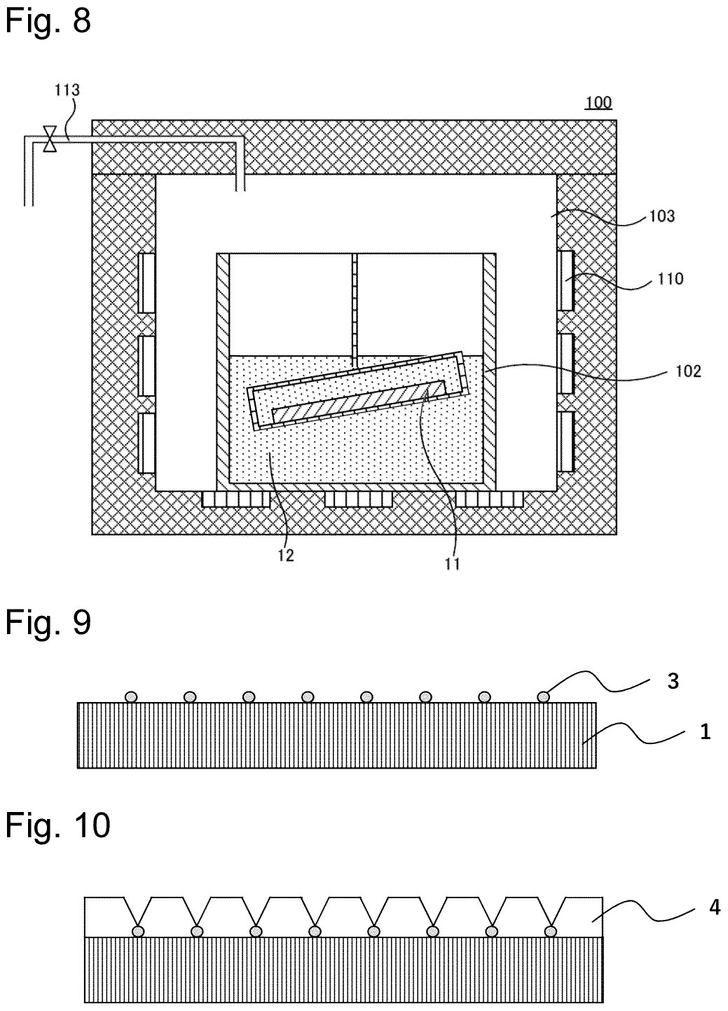

As illustrated in FIG. 6, as a substrate 11 for producing a Group III nitride crystal, a GaN seed crystal substrate (Group III nitride seed crystal) 1 is first prepared. To prevent GaN crystals from growing on the back side of the GaN seed crystal substrate 1, a sapphire substrate 2 is disposed so as to superpose on the back side of the GaN seed crystal substrate 1, and a GaN crystal is formed on the GaN seed crystal substrate 1 by the flux method. The GaN crystal growth step can be performed as follows using, for example, the apparatus illustrated in FIGS. 7 and 8.

### Step of Preparation of GaN Crystal Growth

FIG. 7 is a schematic sectional view illustrating a sectional structure in a state where a substrate 11 is pulled up above a crucible 102 in a Group III nitride crystal manufacturing apparatus 100 to be used in the method for manufacturing a Group III nitride crystal according to first embodiment of the present disclosure. FIG. 8 is a schematic sectional view illustrating a sectional structure in a state where the substrate 11 is immersed in the crucible 102 in the Group III nitride crystal manufacturing apparatus 100 to be used in the method for manufacturing a Group III nitride crystal according to first embodiment of the present disclosure. FIGS. 9 to 12 are schematic sectional views each illustrating one step of the method for manufacturing a Group III nitride crystal according to first embodiment of the present disclosure.

As illustrated in FIG. 7, the Group III nitride crystal manufacturing apparatus 100 has a reaction chamber 103 formed of stainless steel, a heat insulating material, or the like, and a crucible 102 is disposed in the reaction chamber 103. The crucible 102 may be one made of boron nitride (BN), alumina (Al₂O₃), or the like. In addition, a heater 110 is disposed around the reaction chamber 103, and the heater 110 is designed to be able to adjust the temperature inside the reaction chamber 103, especially inside of the crucible 102. In addition, in the Group III nitride crystal manufacturing apparatus 100 is installed a substrate holding mechanism 114 for holding the substrate 11 with GaN seed crystals such that the substrate 11 can be moved up and down. A nitrogen gas supply line 113 for supplying nitrogen gas is connected to the reaction chamber 103, and the nitrogen gas supply line 113 is connected to a raw material gas cylinder (not shown) or the like.

At the time of GaN crystal growth, first, Na, which is to serve as a flux, and a Group III element Ga are put into the crucible 102 in the reaction chamber 103 of the Group III nitride crystal manufacturing apparatus 100. The input amounts of Na and Ga are approximately 85:15 to 50:50 in molar ratio, for example. At this time, a trace additive may be added, as necessary. When these operations are performed in air, Na may be oxidized. Therefore, these operations are preferably performed with an inert gas such as Ar or nitrogen gas being filled. Next, the inside of the reaction chamber 103 is sealed, the temperature of the crucible is set to 800° C. or more and 1000° C. or less, preferably 850° C. or more and 900° C. or less, and nitrogen gas is fed into the reaction chamber 103. At this time, the gas pressure in the reaction chamber 103 is set to 1*10⁶ Pa or more and 1*10⁷ Pa or less, preferably 3*10⁶ Pa or more and 5*10⁶ Pa or less. Increasing the gas pressure in the reaction chamber 103 facilitates nitrogen to dissolve in the Na melted at a high temperature, and adjusting the temperature and the pressure as described above allows GaN crystals to grow at a high rate. Subsequently, holding or stirring and mixing, etc. are performed until Na, Ga, and the trace additive are uniformly mixed. The holding or stirring and mixing is preferably performed for 1 to 50 hours, and more preferably performed for 10 to 25 hours. When the holding or the stirring and mixing is performed for such a time, Na, Ga, and the trace additive can uniformly be mixed. In addition, at this time, if the substrate 11 comes into contact with the melt 12 of Na or Ga that is lower than a predetermined temperature or is not uniformly mixed, etching of the GaN seed crystal substrate 1, precipitation of GaN crystals with poor quality, or the like occurs. Therefore, it is preferable to hold the substrate 11 in an upper portion of the reaction chamber 103 with the substrate holding mechanism 114.

### GaN Nucleation Step

Next, for the nucleation step of growing GaN crystal nuclei, the melt is controlled to have a low degree of supersaturation in order to reduce the nucleation density, which is a feature of the method for manufacturing a Group III nitride crystal according to the present disclosure. The degree of supersaturation is calculated from the difference between the amount of nitrogen dissolved in the melt and the solubility of the Group III nitride. The degree of supersaturation is high when the melt is at a low temperature, and can be reduced by raising the temperature of the melt. The degree of supersaturation depends not only on the temperature of the melt but also on the nitrogen pressure. The nitrogen pressure in an atmosphere affects the concentration of nitrogen dissolved in the melt. Therefore, the degree of supersaturation is high at high pressures, and is low at low pressures. Therefore, regarding the temperature and the pressure in the nucleation step, the temperature is set to 875° C. or more such that the growing GaN crystal nuclei grow sparsely, for example, such that the nucleation density is 1*10⁶/cm² or less. The temperature is appropriately set preferably within a range of 880° C. or more, more preferably within a range of 885° C. or more and less than 900° C. When the temperature exceeds 900° C., nucleation cannot occur, resulting in ungrown. Therefore, the lower limit of the nucleation density is desirably 1*10³/cm².

On the other hand, in the case of controlling by pressure, when the nitrogen pressure is set to 2*10⁶ Pa or less, it is possible to control the nucleation density to the same level as 885° C. or more.

When the melt has successfully been controlled to have a low degree of supersaturation, the substrate 11 is immersed in the melt 12 as illustrated in FIG. 8. In addition, stirring or the like of the melt 12 may be performed during the immersion. As to the stirring of the melt 12, the crucible 102 may be physically moved by swinging, rotating, or the like, or the melt 12 may be stirred using a stirring rod, a stirring blade, or the like. In addition, a thermal gradient may be generated in the melt 12, and the melt 12 may be stirred by heat convection. By stirring, the concentrations of Ga and N in the melt 12 can be kept uniform, and crystals can be stably grown. Then, Ga in the melt 12 and dissolved nitrogen react with each other on a surface of the GaN seed crystal substrate 1, and GaN crystal nuclei are epitaxially grown on the GaN seed crystal substrate 1. By immersing the substrate 11 in the melt 12 for a certain period of time to grow crystals in this state, GaN crystal nuclei 3 can be generated sparsely (in the form of multiple islands) as illustrated in FIG. 9.

### First GaN Crystal Growth Step

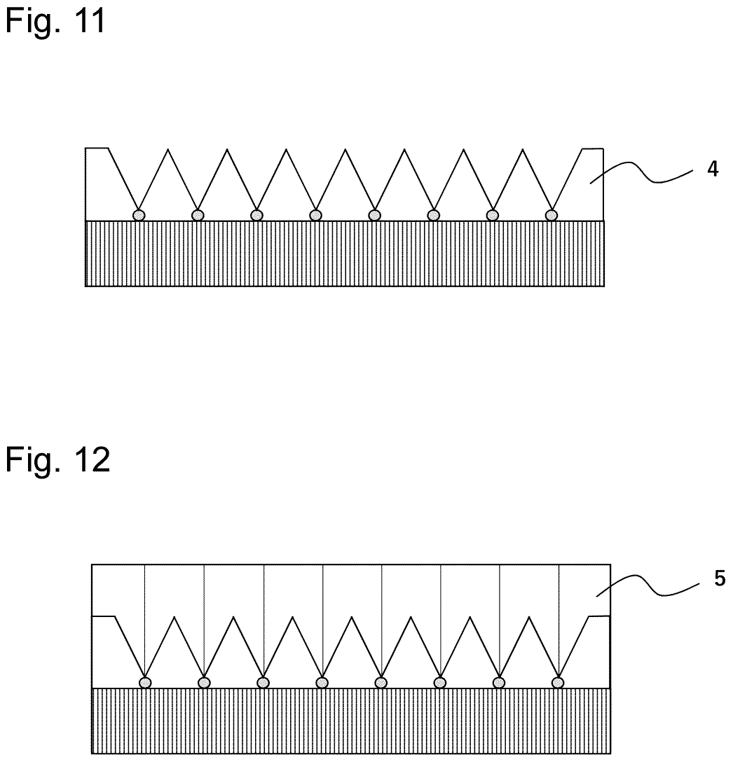

The substrate 11 on which GaN crystal nuclei 3 have been sparsely grown is repeatedly brought alternately in a state where the substrate 11 is pulled up above the melt 12 as illustrated in FIG. 7 and a state where the substrate 11 is immersed in the melt 12 as illustrated in FIG. 8, whereby the immersion of the substrate 11 in the melt 12 and the pulling-up of the substrate 11 from the melt 12 are repeated multiple times. As a result, as illustrated in FIGS. 10 and 11, the dislocations taken over from the GaN seed crystal substrate 1 can be converged on the central portions of the inverted triangular shape centered on the GaN crystal nuclei 3 by the first GaN crystals 4 having an inverted triangular shape or trapezoidal shape in section from each of the GaN crystal nuclei 3. An inverted triangular shape or a trapezoidal shape in section is a depression having an inverted hexagonal pyramid shape when viewed from the surface, and is constituted by facets formed of a (11-22)-plane or a (1-101)-plane.

### Second GaN Crystal Growth Step

When the first GaN crystals 4 having an inverted triangular shape or a trapezoidal shape in section have made gaps have an inverted triangular shape in section, in other words, as illustrated in FIG. 11, have made a flat surface disappear in view from the crystal surface, the second GaN crystal 5 is grown such that the inverted triangular gaps are filled to form the second Group III nitride crystal having a flat surface. Here, the point is that the growth conditions of the first crystal growth step and the second crystal growth step are common because the switching from the first crystal growth step to the second crystal growth step is not controlled on the basis of the growth conditions, and switching to the planarization growth mode is performed on the basis of the disappearance of a flat surface as viewed from the surface of the grown crystal. In the second crystal growth step, it is necessary to fill inverted triangular gaps, and to realize such a growth mode, it is necessary to make the degree of supersaturation high. On the other hand, to make the degree of supersaturation high means to increase the driving force for crystal growth, and leads to generation of a large number of GaN crystals at the interface between the melt 12 and the crucible 102, the contact portion with the substrate holding mechanism 114, and the like, and has a problem that the growth of GaN crystals on the substrate 11 is thereby inhibited.

On the other hand, it is known that the nitrogen concentration at a place in the melt is higher as the place is closer to the surface of the melt because nitrogen dissolves from the surface of the melt, and to achieve a high degree of supersaturation, it is effective to grow GaN crystals at the very vicinity of the surface of the melt. However, in a high-temperature and high-pressure container and in a situation where crystal growth and raw material consumption occur at the same time, it is very difficult to hold the substrate 11 at the very vicinity of the surface of the melt with high accuracy for a long time. Accordingly, the inventors have considered that a thin film of the melt is formed on the surface of the substrate 11 by immersing the substrate 11 in the melt 12 and then pulling it up from the melt 12. As a result of an experiment conducted on the basis of this idea, the inventors have succeeded in realizing a growth mode in which the surface becomes flat under both of a nitrogen pressure and a temperature condition at which a low degree of supersaturation to inhibit the generation of polycrystals is attained. On the other hand, it has also been found that since GaN crystals are grown from the film-like melt, Ga in the melt is depleted as crystals grow, and the growth eventually stops. Therefore, to realize a growth thickness necessary for filling pyramidal gaps, a second GaN crystal growth step involving repeating immersion and pulling-up multiple times has been devised. For example, by repeating immersion and pulling-up about 50 to 500 times, a second GaN crystal 5 having a flat surface was obtained.

To stably form the film-like melt on the entire surface of the substrate 11, it is preferable to incline the substrate 11 by about 5 to 15 degrees with respect to the liquid surface of the melt 12. By inclining the substrate within this range, the coat film can be controlled to have a suitable thickness owing to the balance among the surface shape of the substrate 11, the surface tension of the melt 12, and the gravity, and the melt can be inhibited from accumulating on the substrate 11. The substrate 11 may be always inclined as illustrated in FIG. 7, or may be inclined with respect to the liquid surface of the melt at least once during the period in which the substrate is pulled up above the melt.

Here, regarding the time of immersion in the melt 12 and the time of pulling-up above the melt 12, it is efficient to set the time of pull-up above the melt to a time until Ga in the film-like melt is depleted up, and the amount of growth thickness per immersion is desirably 5 to 10 μm/time, and the immersion time is preferably 30 to 60 minutes, and the pulling-up time is preferably 10 to 30 minutes, for example. The temperature of the first and second GaN crystal growth steps is preferably set, for example, about 2 to 10° C. higher than the temperature of the GaN nucleation step to inhibit the generation of polycrystals. By setting higher than the temperature of the GaN nucleation step in this manner, the growth rate can be controlled, the occurrence of steps and giant steps can be inhibited, and the occurrence of pinning including impurities or dislocations can also be inhibited.

The number of times the substrate is immersed and pulled up may be set according to the thickness of the film to be formed. For example, when the film formation rate per unit time is 6 μm/h, the immersion time is 60 minutes, and the pulling-up time is 15 minutes, it is necessary to perform 250 sets of the immersion and the pulling-up to obtain a film thickness of 1500 μm. In this case, the time of the first and second GaN crystal growth steps is about 312.5 hours.

After the completion of the second GaN crystal growth step, it is necessary to return the temperature and pressure to normal temperature and normal pressure in order to take out the GaN crystal. When the temperature and the pressure are returned to normal temperature and normal pressure, the degree of supersaturation of the melt 12 greatly fluctuates, and if the substrate 11 remains immersed, etching of the grown GaN crystal and precipitation of a low-quality GaN crystal occur. Therefore, after the completion of the second GaN crystal growth step, it is preferable to return the temperature and the pressure to normal temperature and normal pressure with the substrate 11 pulled up above the melt 12.

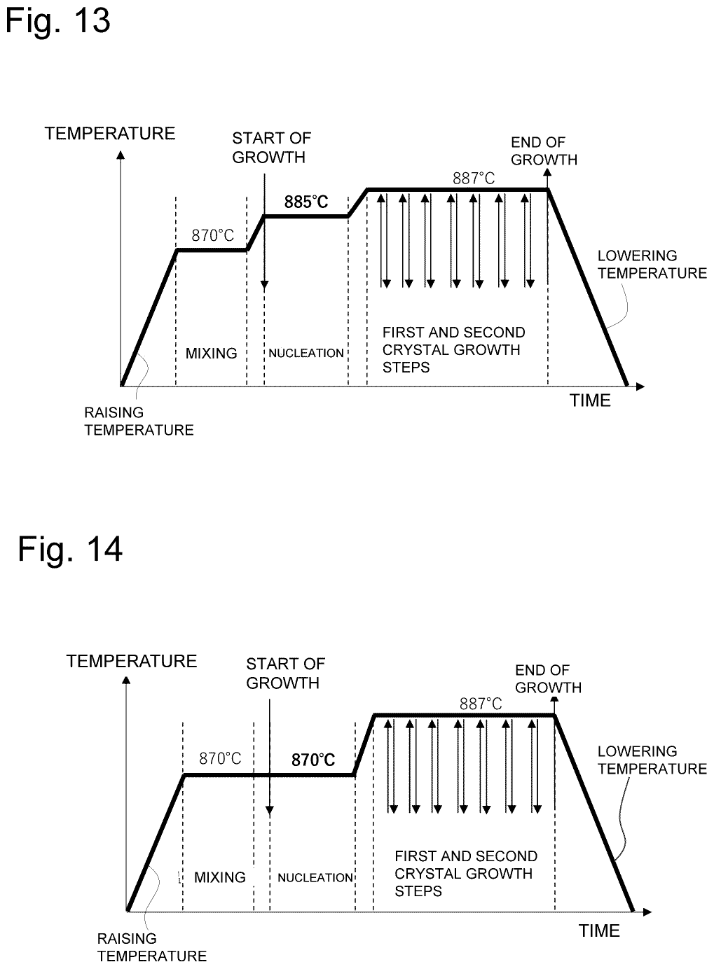

In FIG. 13 is shown a temperature profile of one example of the method for manufacturing a GaN crystal to be used in the method for manufacturing a Group III nitride crystal according to first embodiment of the present disclosure. In addition, a temperature profile of one example of a conventional method for manufacturing a GaN crystal is shown in FIG. 14. Conventionally, for the purpose of increasing the nucleation density in the nucleation step, the temperature is set to 870° C. to keep the degree of high supersaturation high, whereas in the method for manufacturing a Group III nitride crystal according to the present disclosure, the temperature in the nucleation step is set to 875° C. or more, 880° C. or more as a preferable range, or 885° C. or more as a more preferable range to keep the degree of supersaturation low.

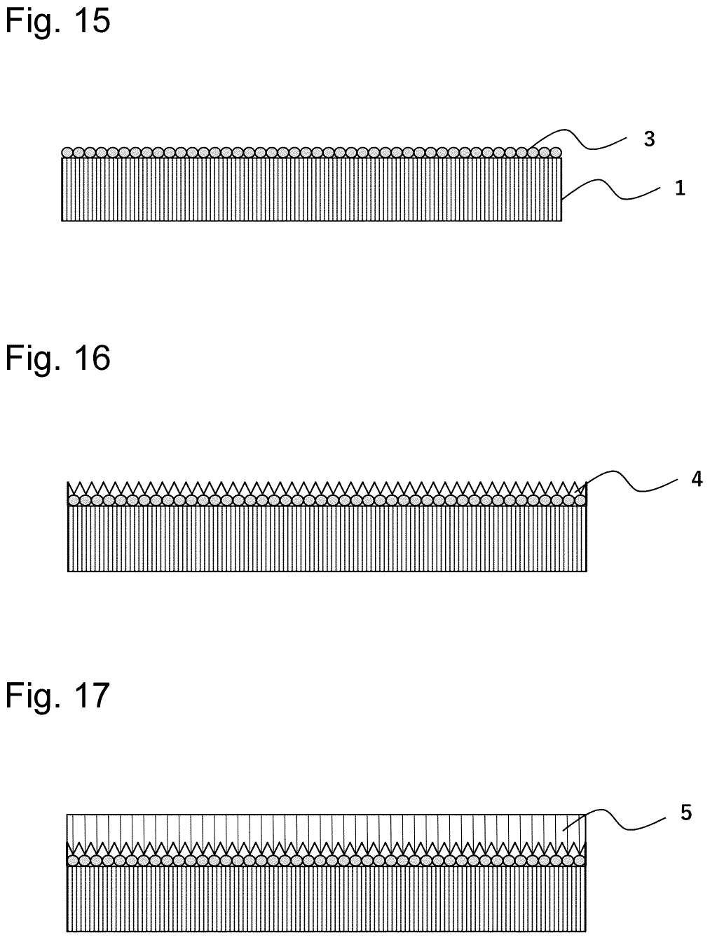

When nucleation is performed by the method for manufacturing a Group III nitride crystal according to the present disclosure, GaN crystal nuclei 3 can be generated sparsely (in the form of multiple islands) as illustrated in FIG. 9 described above. On the other hand, when nucleation is performed in the conventional example, GaN crystal nuclei are generated in a high density as illustrated in FIG. 15. When the first GaN crystal growth is performed after the nucleation is performed in the conventional example, it is possible to render the dislocation density lower by growing the first GaN crystals 4 having an inverted triangular shape or a trapezoidal shape in section from each of the GaN crystal nuclei 3 as illustrated in FIG. 16. In the case of FIG. 16, however, the number of places where dislocations are concentrated increases as compared with the examples of the present disclosure (FIGS. 10 and 11). Then, as illustrated in FIG. 17, on the surface on which the second GaN crystal growth has been performed, dislocations increase as compared with the examples of the present disclosure.

The dislocation density can be evaluated through, for example, evaluation by multiphoton-excitation photoluminescence (MPPL), peak profile analysis of X-ray diffraction, or TEM observation as described above.

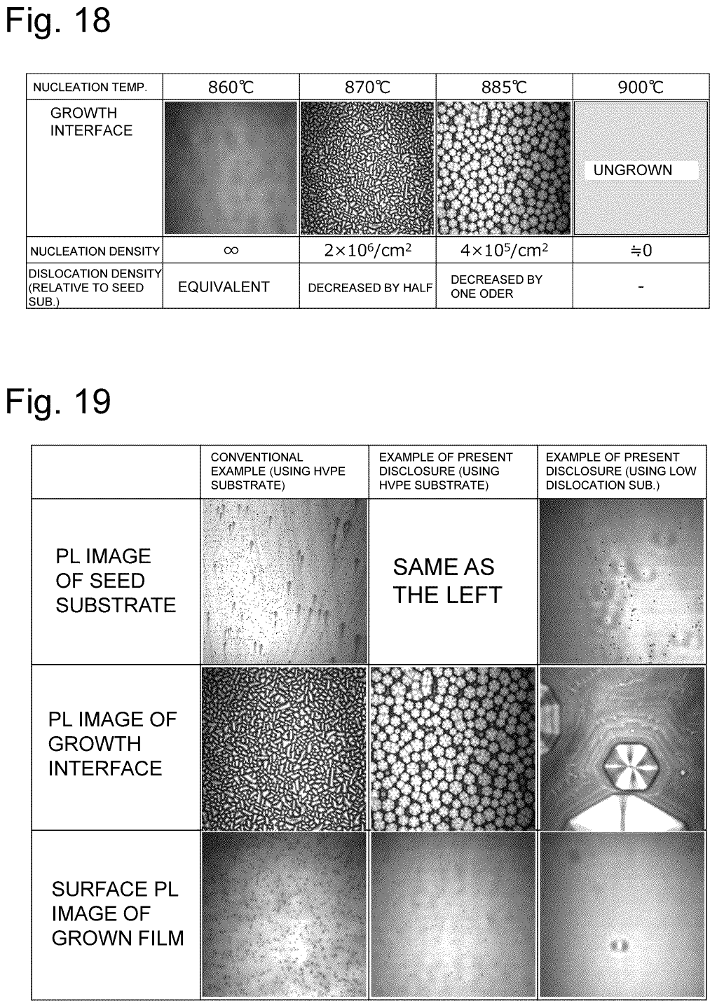

FIG. 18 is a diagram showing a comparison between a 250 μm square field image of multiphoton-excitation photoluminescence (MPPL) near a growth interface in a nucleation step of a Group III nitride crystal in a method for manufacturing a Group III nitride crystal according to first embodiment of the present disclosure and a 250 μm square field image of multiphoton-excitation photoluminescence (MPPL) near a growth interface in a nucleation step of a Group III nitride crystal in the conventional example.

In FIG. 18 are shown MPPL images near a growth interface when the temperature at the time of GaN crystal nucleation was 860° C., 870° C., 885° C., or 900° C. At 860° C., the growth interface has been taken over well, but the dislocation density near the growth surface is equivalent to that of the seed substrate. At 870° C., there are nucleation points in the sixth power/cm² range at the growth interface, and the dislocation density near the growth surface decreases by half relative to the seed substrate. At 885° C. of the example of the present disclosure, there are nucleation points in the fifth power/cm² range at the growth interface, and hexagonal growth (growth in an inverted triangular shape in section) is observed. This configuration is an inverted hexagonal pyramid depression, and is constituted by facets composed of a (11-22)-plane or a (1-101)-plane. The dislocation density near the growth surface at 885° C. decreases by one order relative to the seed substrate. On the other hand, nucleation did not occur at 900° C. Therefore, the nucleation temperature of the present disclosure is 875° C. or more, which is higher than that in the conventional example, and a dislocation reduction effect can be confirmed. Furthermore, the nucleation temperature is preferably 880° C. or more, or not less than 885° C., which is that of the example, and less than 900° C. In addition, in the case of being specified by a nucleation density, it is preferably in the fifth power/cm² range or less. The lower limit is the square/cm² range or more, and a nucleation density less than this leads to ungrown.

FIG. 19 is a diagram showing a comparison among 250 μm square field images of multiphoton-excitation photoluminescence (MPPL) near growth surfaces of Group III nitride crystals to be used in first embodiment of the present disclosure and a 250 μm square field image of multiphoton-excitation photoluminescence (MPPL) near a growth surface of a Group III nitride crystal to be used in a conventional example. In FIG. 19 are shown a comparison between the conventional example and the present disclosure in which crystals were grown on a GaN seed substrate produced by the HVPE method, and a result of crystal growth by the present disclosure on a GaN seed substrate produced by the flux method.

The left column of FIG. 19 shows a case in which, nucleation was performed at 870° C. of the conventional example on a GaN seed substrate produced by the HVPE method, followed by crystal growth. The upper row is the 250 μm square field image of multiphoton-excitation photoluminescence (MPPL) of the GaN seed substrate produced by the HVPE method, and the dislocation density is 3.6*10⁶/cm². The middle row is the MPPL image at the growth interface, and the lower row is the MPPL image near the crystal growth surface. The dislocation density near the crystal surface is 1.0*10⁶/cm², which is about half of that of the seed substrate.

The central column of FIG. 19 shows a case in which, nucleation was performed at 885° C. of the present disclosure on a GaN seed substrate produced by the HVPE method, followed by crystal growth. The nucleation density of the middle row is lower than that in the conventional example, and the dislocation density near the crystal growth surface of the lower row is 3.3*10⁵/cm², which is one order lower than that of the seed substrate.

Further, the right column of FIG. 19 shows the result of nucleation performed at 885° C. of the present disclosure on a low dislocation seed substrate produced by the flux method, followed by crystal growth. The upper row is the 250 μm square field image of multiphoton-excitation photoluminescence (MPPL) of a GaN seed crystal produced by the flux method, and the dislocation density is 1.6*10⁵/cm². The nucleation density of the middle row is lower than that of the seed substrate of the HVPE method, and the dislocation density near the crystal growth surface of the lower row is 1.3*10⁴/cm², which is one order lower than that of the seed substrate.

### Group III Nitride Crystal

A Group III nitride crystal obtained by the method for manufacturing a Group III nitride crystal according to first embodiment is a Group III nitride crystal grown on a Group III nitride seed crystal, wherein a nucleation density at a growth interface on the Group III nitride seed crystal is 1*10⁶/cm² or less.

FIG. 4 shows a classification of the surface dislocation density of the GaN substrate produced in the conventional example, and the places where the surface dislocation density was in the fourth power range or less accounted for 46.25%. On the other hand, in the GaN substrate produced in the example of the present disclosure of FIG. 5, the proportion of the places where the surface dislocation density was in the fourth power range or less increased to 86.25%. This is considered to be because dislocation at a region (triple point) surrounded by the multiple seed crystals described above was reduced by hexagonal growth (growth in an inverted triangular shape in section) in the example of the present disclosure. As described above, the problem in the conventional example can be solved by the example of the present disclosure.

### Other Embodiments

In the above embodiment, when a trace additive is added together with Na and Ga, it is possible to adjust the electrical conductivity and band gap of the resulting GaN. Examples of the trace additive include boron (B), thallium (TI), calcium (Ca), compounds containing calcium (Ca), silicon (Si), sulfur (S), selenium (Se), tellurium (Te), carbon (C), oxygen (O), aluminum (Al), indium (In), alumina (Al₂O₃), indium nitride (InN), silicon nitride (Si₃N₄), silicon oxide (SiO₂), indium oxide (In₂O₃), zinc (Zn), magnesium (Mg), zinc oxide (ZnO), magnesium oxide (MgO), and germanium (Ge). These trace additives may be added alone or in combination of two or more.

In addition, the mode in which Na is used as the flux has been described, but the present disclosure is not limited thereto, and an alkali metal other than Na may be used. Specifically, the flux may contain at least one selected from the group consisting of Na, Li, K, Rb, Cs, and Fr, and may be a mixed flux of Na and Li, for example.

Furthermore, in the above description, the mode of producing a crystal of GaN as a Group III nitride has been described, but the present disclosure is not limited thereto. The Group III nitride of the present disclosure can be a binary, ternary, or quaternary compound containing a Group III element (Al, Ga, or In) and nitrogen, and may be, for example, a compound represented by the general formula Al_{1-x-y}Ga_{y}InₓN wherein x and y satisfy 0≤x≤1, 0≤y≤1, and 0≤1-x-y≤1. The Group III nitride may contain p-type or n-type impurities. Although GaN has been described as the material of the Group III nitride seed crystal substrate 1, the compound described above may be used.

The use of the method for manufacturing a Group III nitride crystal according to the present disclosure makes it possible to obtain a high-quality Group III nitride crystal having few crystal defects, and for example, makes it possible to manufacture an LED element or the like having little light emission unevenness or little decrease in luminance in a good yield.

### EXPLANATION OF REFERENCES

1 GaN seed crystal substrate (Group III nitride seed crystal substrate)
2 Sapphire substrate
3 GaN crystal nucleus (Group III nitride crystal nucleus)
4 First GaN crystal (first Group III nitride crystal (growth portion having inverted triangular shape in section))
5 Second GaN crystal (second Group III nitride crystal (flat thick growth portion))
11 Substrate
12 Melt
100 Group III nitride crystal manufacturing apparatus
102 Crucible
103 Reaction chamber
110 Heater
113 Nitrogen gas supply line

What is claimed is:

1. A method for manufacturing a Group III nitride crystal, the method comprising:
bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method comprising:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a temperature is set to 875° C. or more and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

2. The method for manufacturing a Group III nitride crystal according to claim 1, wherein in the course of growing the plurality of island-like Group III nitride crystal nuclei, on setting the temperature to 880° C. or more, thereby the nucleation density is lowered and the plurality of island-like Group III nitride crystal nuclei are grown.

3. The method for manufacturing a Group III nitride crystal according to claim 1, wherein in the course of growing a plurality of island-like Group III nitride crystal nuclei, on setting the temperature to 885° C. or more and less than 900° C., thereby the nucleation density is lowered and the plurality of island-like Group III nitride crystal nuclei are grown.

4. A method for manufacturing a Group III nitride crystal, the method comprising: bringing a surface of a Group III nitride seed crystal into contact with a melt including at least one Group III element selected from among gallium, aluminum, and indium and an alkali metal in an atmosphere containing nitrogen to cause the Group III element and the nitrogen to react with each other in the melt to grow a Group III nitride crystal on the Group III nitride seed crystal, the method comprising:
growing a plurality of island-like Group III nitride crystal nuclei on the surface of the Group III nitride seed crystal;
growing a first Group III nitride crystal having an inverted triangular shape or a trapezoidal shape in section from each of the plurality of island-like Group III nitride crystal nuclei; and
growing a second Group III nitride crystal such that the second Group III nitride crystal fills a depression of the first Group III nitride crystal to form the second Group III nitride crystal having a flat surface,
wherein in the course of growing the plurality of island-like Group III nitride crystal nuclei, a gas pressure in a reaction chamber is set to a pressure of 2*10⁶ Pa or less and a nucleation density is set to 1*10⁶/cm² or less, and
in the course of growing the first Group III nitride crystal and growing the second Group III nitride crystal, immersion of the Group III nitride seed crystal in the melt and pulling up from the melt are repeated a plurality of times.

5. The method for manufacturing a Group III nitride crystal according to claim 1, wherein the Group III nitride seed crystal is a low dislocation substrate having a dislocation density of 5*10⁵/cm² or less.

6. A Group III nitride crystal, being a Group III nitride crystal grown on a Group III nitride seed crystal,
wherein a nucleation density at a growth interface on the Group III nitride seed crystal is 1*10⁶/cm² or less.
